(19) United States
(12) Patent Application Publication
(10) Pub. No.: US 2010/0149014 A1
(43) Pub. Date: Jun. 17, 2010

(54) SEMICONDUCTOR INTEGRATED CIRCUIT

(76) Inventor: Yoshinori HASHIMOTO, Osaka (JP)

Correspondence Address: BIRCH STEWART KOLASCH & BIRCH, PO BOX 747, FALLS CHURCH, VA, 22040-0747, US

(21) Appl. No.: 12/540,413

(22) Filed: Aug. 13, 2009

(30) Foreign Application Priority Data
Dec. 17, 2008 (JP) 2008-321209

(51) Int. Cl. H03M 1/66

(52) U.S. Cl. 341/144

(57) ABSTRACT

A semiconductor integrated circuit 10 includes a digital/analog conversion circuit 6. Test signals, which are supplied through signal lines Sig0T through Sig3T, are supplied to the digital/analog conversion circuit 6 via input terminals 5A through 5D, respectively. The digital/analog conversion circuit 6 converts the test signals (digital signals) into an analog signal and supplies the analog signal via an output terminal 7 to a signal line So. The analog signal supplied through the signal line So is externally outputted via a external output terminal 4. This achieves a semiconductor integrated circuit suitable for miniaturization.

This Nonprovisional application claims priority under 35 U.S.C. §119(a) on Patent Application No. 2008-321209 filed in Japan on Dec. 17, 2008, the entire contents of which are hereby incorporated by reference.

### TECHNICAL FIELD

The present invention relates to a semiconductor integrated circuit for externally outputting signals in a normal operation (actual operation) and in a test mode, in which it is checked whether or not a circuit operates normally, of a general semiconductor integrated circuit.

### BACKGROUND ART

In these years, a semiconductor integrated circuit has been miniaturized. This causes a semiconductor chip to have become smaller in size. This leads to a restriction of the number of terminals (input and output terminals) which a circuit size is allowed to have.

Accordingly, it is becoming more difficult for such a semiconductor integrated circuit to include a large number of terminals, which are unnecessary for normal operations of respective circuits, such as (i) test terminals to which respective test circuits are connected for checking whether or not the circuits operate normally and (ii) monitor terminals to which respective monitor circuits are connected for monitoring whether or not the circuits operate normally.

In view of the circumstances, Patent Literature 1 discloses a test circuit for carrying out a divided test with the use of a small number of external output terminals. According to such a divided test, a multiplexer is provided between circuit blocks. A predetermined control signal is supplied to the multiplexer so that the divided test for the circuit blocks can be carried out via a single external output terminal.

### Citation List

Patent Literature 1

Japanese Patent Application Publication, Tokukaihei, No. 10-221408 A (Publication Date: Aug. 21, 1998)

### SUMMARY OF INVENTION

Technical Problem

In a case where the test circuit outputs a digital signal (encoded signal) indicative of a checked result of whether or not a circuit operates normally, it is necessary to prepare as many signal lines as bits of the digital signal in order to externally output the digital signal indicative of the checked result. For example, in order to externally output a 4-bit digital signal indicative of a checked result, it is necessary to prepare four signal lines.

Note that a single external output terminal (testing terminal) must be provided with respect to a single signal line. In a case where a multiple-bit digital signal indicative of a checked result is to be externally outputted in the test circuit disclosed in Patent Literature 1, the number of external output terminals needs to be increased, accordingly.

Moreover, according to the test circuit in Patent Literature 1, it is necessary to think out a configuration of the test circuit itself. This causes the test circuit inevitably to have a more complex configuration than the known test circuits.

For the reasons described above, there occurs a problem that the technique disclosed in Patent Literature 1 is not suitable for miniaturization of a semiconductor integrated circuit.

Solution to Problem

The present invention is accomplished in view of the above problem, and its object is to provide a semiconductor integrated circuit suitable for miniaturization.

In order to attain the object, a semiconductor integrated circuit of the present invention includes: a test circuit for (i) checking whether or not a circuit operates normally and (ii) outputting an encoded signal indicating a result thus checked; and an analog conversion circuit for (i) converting the encoded signal supplied from the test circuit into an analog signal and (ii) externally outputting the analog signal.

With the configuration, the test circuit supplies to the analog conversion circuit the encoded signal indicative of a checked result as to whether or not the circuit operates normally. The analog conversion circuit converts the encoded signal into an analog signal which can cause digital signals such as binary digital signals to be changed into a multiple-value. Then, the analog signal thus obtained is externally outputted. This makes it possible to convert a multiple-bit digital signal (various types of encoded signals) into a single analog signal, and then externally output such a single analog signal. As such, according to the semiconductor integrated circuit of the present invention, it is possible to reduce the number of output terminals via which the signal, indicating the result checked by the test circuit, is outputted.

Moreover, with the configuration, it is possible, without particularly thinking out the configuration of the test circuit itself, to reduce the number of output terminals via which the signal, indicating the result checked by the test circuit, is outputted. This allows a known test circuit to be used, thereby avoiding the complex configuration of the test circuit.

For the reasons described above, the semiconductor integrated circuit of the present invention is suitable for miniaturization.

### ADVANTAGEOUS EFFECTS OF INVENTION

As described above, the semiconductor integrated circuit of the present invention includes: a test circuit for (i) checking whether or not a circuit operates normally and (ii) outputting an encoded signal indicating a result thus checked; and an analog conversion circuit for (i) converting the encoded signal supplied from the test circuit into an analog signal and (ii) externally outputting the analog signal.

Accordingly, the present invention has an effect of being suitable for miniaturization of semiconductor integrated circuits.

### BRIEF DESCRIPTION OF DRAWINGS

FIG. 1

FIG. 1 is a block diagram illustrating a schematic structure of a semiconductor integrated circuit of the present invention.

FIG. 2

FIG. 2 is a view illustrating an example of a specific circuit configuration of a digital/analog conversion circuit.

FIG. 3

FIG. 3 is a view illustrating another example of a specific circuit configuration of a digital/analog conversion circuit.

FIG. 4

FIG. 4 is a block diagram illustrating a schematic structure of another semiconductor integrated circuit of the present invention.

FIG. 5

FIG. 5 is a block diagram illustrating a schematic configuration of a modified example of the semiconductor integrated circuit shown in FIG. 4.

FIG. 6

FIG. 6 is a block diagram illustrating a schematic structure of yet another semiconductor integrated circuit of the present invention.

FIG. 7

FIG. 7 is a block diagram illustrating a schematic structure of the semiconductor integrated circuit of the present invention without a test circuit.

FIG. 8

FIG. 8 is a block diagram illustrating a schematic structure of a semiconductor integrated circuit on which the present invention is premised.

FIG. 9a

FIG. 9a is a view illustrating an example of a specific circuit configuration of a data latch circuit.

FIG. 9b

FIG. 9b is a view illustrating another example of a specific circuit configuration of a data latch circuit.

FIG. 10

FIG. 10 is a view illustrating an example of a specific circuit configuration for suspending operation of the DA conversion circuit according to a standby signal in a case where the DA conversion circuit shown in FIG. 2 is used.

FIG. 11

FIG. 11 is a view illustrating an example of a specific circuit configuration for halting operation of the DA conversion circuit according to a standby signal in a case where the DA conversion circuit shown in FIG. 3 is used.

### DESCRIPTION OF EMBODIMENTS

### [Prerequisite Technique]

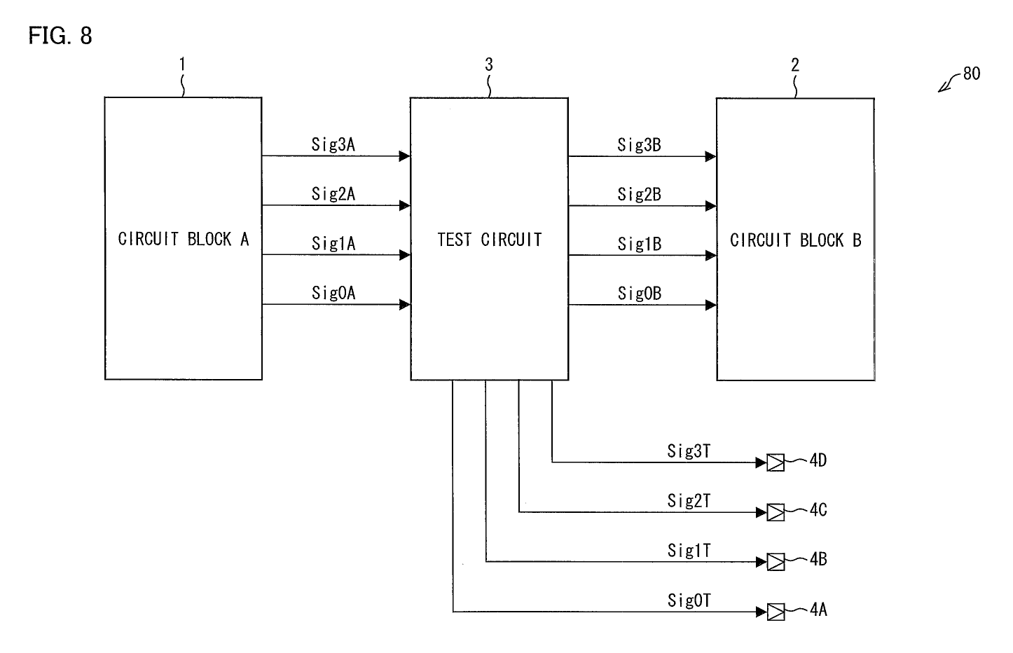

FIG. 8 is a block diagram illustrating a schematic structure of a semiconductor integrated circuit on which the present invention depends.

A semiconductor integrated circuit 80 shown in FIG. 8 includes: a circuit block (circuit) 1 serving as a circuit block A; a circuit block (circuit) 2 serving as a circuit block B; and a test circuit 3.

The circuit block 1 is connected to: one end of a signal line Sig0A; one end of a signal line Sig1A; one end of a signal line Sig2A; and one end of a signal line Sig3A.

The other ends of the signal line Sig0A, the signal line Sig1A, the signal line Sig2A and the signal line Sig3A are connected to one ends of signal lines Sig0B, Sig1B, Sig2B and Sig3B, respectively, via the test circuit 3.

The circuit block 2 is connected to: the other end of the signal line Sig0B; the other end of the signal line Sig1B; the other end of the signal line Sig2B; and the other end of the signal line Sig3B.

The other ends of the signal lines Sig0A, Sig1A, Sig2A and Sig3A are further connected to one ends of signal lines Sig0T, Sig1T, Sig2T and Sig3T, respectively, via the test circuit 3.

The other ends of the signal lines Sig0T, Sig1T, Sig2T and Sig3T are connected to external output terminals 4A, 4B, 4C and 4D, respectively.

Each of the circuit blocks 1 and 2 is, for example, a general-purpose circuit, including a CPU (Central Processing Unit) core, for performing a predetermined logical operation process. Moreover, each of the circuit blocks 1 and 2 is included in, for example, an ASIC (Application Specific Integrated Circuit) or an MCM (Multi Chip Module), and is suitably used as each of various communication devices, an automobile, a controller circuit for home electric appliances, or the like.

The test circuit 3 is a known test circuit for checking whether or not the circuit blocks 1 and 2 operates normally.

For example, during an evaluation made after manufacturing the semiconductor integrated circuit 80 and during a test for shipping the semiconductor integrated circuit 80, it is necessary to check whether or not (i) the circuit blocks 1 and 2 operate normally and (ii) the circuit blocks 1 and 2 are appropriately connected with each other.

In order to carry out the checking operations with respect to the circuit block 1, the test circuit 3 supplies test signals, which are supplied from the circuit block 1 via the signal lines Sig0A through Sig3A, to the signal lines Sig0T through Sig3T connected to the signal lines Sig0A through Sig3A, respectively. The test signals are externally outputted (i.e., digital signals, serving as encoded signals, indicative of checked results as to whether or not a circuit operates normally), via the external output terminals 4A through 4D to which the other ends of the signal lines Sig0T through Sig3T are connected. The checking operations for the circuit block 1 can be carried out by measuring the test signals outputted via the external output terminals 4A through 4D.

Moreover, in order to carry out the checking operations with respect to the circuit block 2, the test circuit 3 supplies new test signals, which are produced based on the test signals supplied from the circuit block 1 via the signal lines Sig0A through Sig3A, to the circuit block 2 via the signal lines Sig0B through Sig3B connected to the signal lines Sig0A through Sig3A, respectively. The new test signals thus produced by the test circuit 3 are externally outputted via output terminals (not illustrated) of the circuit block 2. The checking operations for the circuit block 2 can be carried out by measuring the new test signals supplied from the output terminals of the circuit block 2.

Note that binary digital signals (encoded signals) are used as the test signals and the new test signals. Moreover, each of the signal lines Sig0A through Sig3A, Sig0B through Sig3B, and Sig0T through Sig3T can transmit a 1-bit digital signal. That is, according to the semiconductor integrated circuit 80, digital signals of maximum 4 bits (i.e., 16 digital values in total) can be used as the test signals which are supplied through the signal lines Sig0A through Sig3A, and Sig0T through Sig3T, and can be used as the new test signals which are supplied through the signal lines Sig0B through Sig3B.

In a case where test signals, which are supplied from the test circuit 3, are digital signals, it is necessary to prepare as many signal lines as bits of the digital signals, in order to externally output the test signals. This applies also to the semiconductor integrated circuit 80. That is, the semiconductor integrated circuit 80 includes four signal lines Sig0T through Sig3T so as to externally output 4-bit digital signals as the respective test signals. Particularly, in a case where the 4-bit digital signals are to be externally outputted, the signal lines Sig0T through Sig3T have to be connected with the external output terminals 4A through 4D, respectively.

As a result, the semiconductor integrated circuit 80 has to include four output terminals (the external output terminals 4A through 4D), which are not necessary for normal operation, in order to carry out the checking operations with respect to the circuit block 1. This causes a problem that the semiconductor integrated circuit 80 is not suitable for miniaturization.

### Embodiments

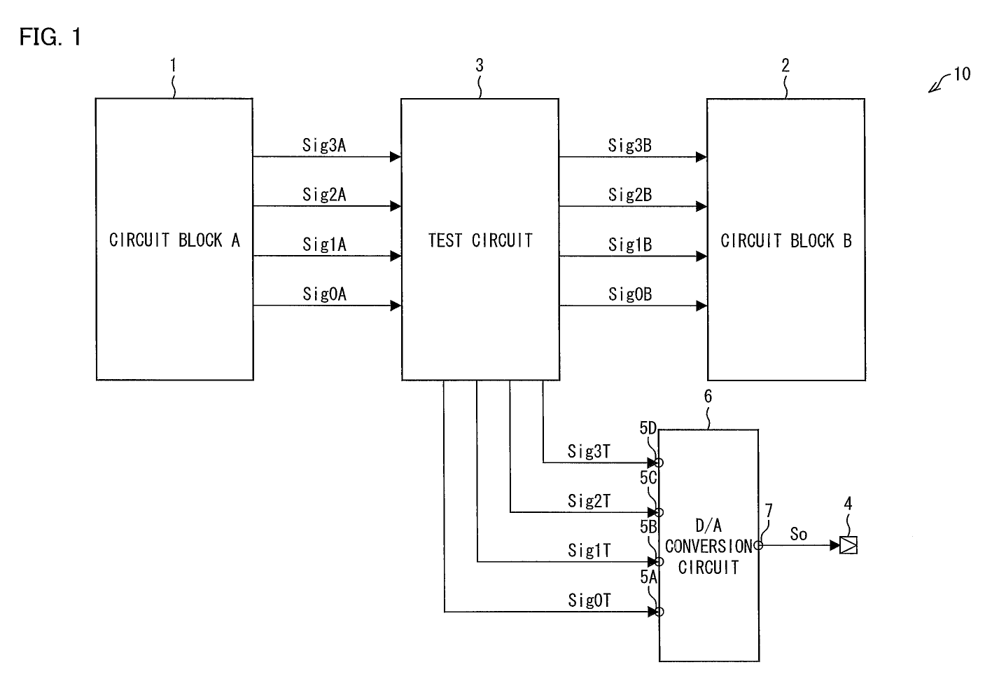

FIG. 1 is a block diagram illustrating a schematic structure of a semiconductor integrated circuit of the present invention.

A semiconductor integrated circuit 10 shown in FIG. 1 includes the configuration of the semiconductor integrated circuit 80 shown in FIG. 8, and further includes a digital/analog conversion circuit (hereinafter, referred to as “DA conversion circuit”) 6.

In the DA conversion circuit (analog conversion circuit) 6, its input terminals 5A, 5B, 5C and 5D are connected to the other ends of the signal lines Sig0T, Sig1T, Sig2T and Sig3T, respectively. Moreover, an output terminal 7 of the DA conversion circuit 6 is connected to one end of a signal line So. The other end of the signal line So is connected with an external output terminal 4.

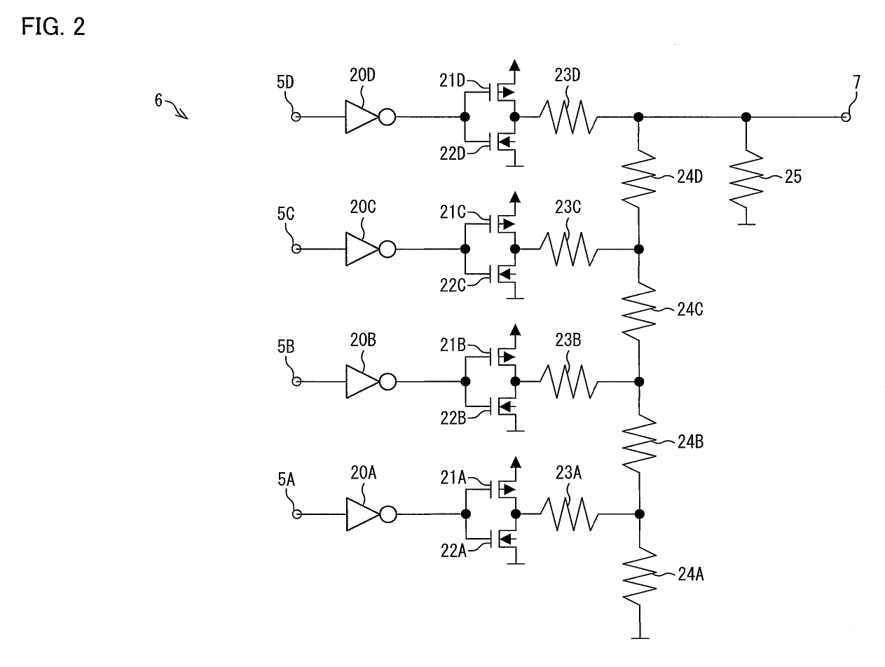

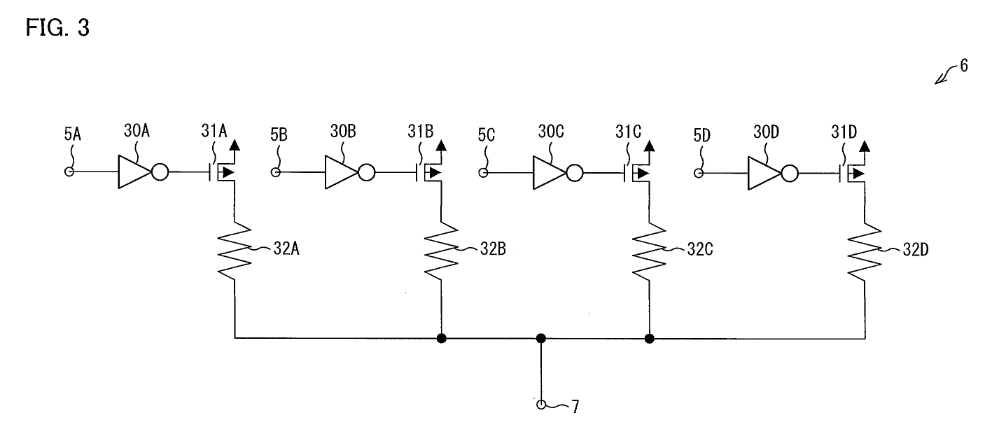

The test signals, which are supplied through the respective signal lines Sig0T through Sig3T, are supplied to the DA conversion circuit 6, via the respective input terminals 5A through 5D. The DA conversion circuit 6 converts the test signals (digital signals) into an analog signal, and outputs the analog signal thus converted to the signal line So via the output terminal 7. Then, the analog signal is externally outputted via the external output terminal 4. The checking operations for the circuit block 1 can be carried out by measuring the analog signal outputted via the external output terminal 4. Note that, the DA conversion circuit 6 is configured to have the four input terminals (input terminals for encoded signals) 5A through 5D but a single output terminal (output terminal for an analog signal) 7. That is, the number of the output terminal is fewer than that of the input terminals. Note that the DA conversion circuit 6 is explained later in detail, with reference to FIGS. 2 and 3.

According to the semiconductor integrated circuit 10, the test signals, which are binary digital signals and are supplied from the test circuit 3 to the signal lines Sig0T through Sig3T, are converted by the DA conversion circuit 6 into an analog signal which can cause the binary digital signals to be changed into a multiple-value, and then the analog signal is externally outputted. Here, the test signals (i.e., 4-bit digital signals) can be converted into a single analog signal having 16 kinds of amplitudes, and then the analog signal is externally outputted. Accordingly, the semiconductor integrated circuit 10 is suitable for miniaturization because the semiconductor integrated circuit 10 requires only a single output terminal (only the external output terminal 4), which is not necessary for normal operation and is necessary for carrying out the checking operations with respect to the circuit block 1.

FIG. 2 is a view illustrating an example of a specific circuit configuration of the DA conversion circuit 6.

The DA conversion circuit 6 shown in FIG. 2 includes: inverters 20A through 20D; p-channel type MOSFETs (hereinafter, referred to as “p-transistors”) 21A through 21D; n-channel type MOSFETs (hereinafter, referred to as “n-transistors”) 22A through 22D; resistors 23A through 23D; resistors 24A through 24D; and a resistor 25. Note that the “MOSFET” is an abbreviation for “Metal-Oxide Semiconductor Field Effect Transistor”.

The input terminal 5A is connected to an input terminal of the inverter 20A. An output terminal of the inverter 20A is connected to gate terminals of the p-transistor 21A and the n-transistor 22A. A source terminal of the n-transistor 22A is grounded. A source terminal of the p-transistor 21A is connected to a reference voltage source (not illustrated) for supplying a voltage VDD or determining a voltage of an analog signal to be outputted. Drain terminals of the p-transistor 21A and the n-transistor 22A are connected to one another, and are connected to one end of the resistor 23A.

The input terminal 5B is connected to an input terminal of the inverter 20B. An output terminal of the inverter 20B is connected to gate terminals of the p-transistor 21B and the n-transistor 22B. A source terminal of the n-transistor 22B is grounded. A source terminal of the p-transistor 21B is connected to the reference voltage source (not illustrated). Drain terminals of the p-transistor 21B and the n-transistor 22B are connected to one another, and are connected to one end of the resistor 23B.

The input terminal 5C is connected to an input terminal of the inverter 20C. An output terminal of the inverter 20C is connected to gate terminals of the p-transistor 21C and the n-transistor 22C. A source terminal of the n-transistor 22C is grounded. A source terminal of the p-transistor 21C is connected to the reference voltage source (not illustrated). Drain terminals of the p-transistor 21C and the n-transistor 22C are connected to one another, and are connected to one end of the resistor 23C.

The input terminal 5D is connected to an input terminal of the inverter 20D. An output terminal of the inverter 20D is connected to gate terminals of the p-transistor 21D and the n-transistor 22D. A source terminal of the n-transistor 22D is grounded. A source terminal of the p-transistor 21D is connected to the reference voltage source (not illustrated). Drain terminals of the p-transistor 21D and the n-transistor 22D are connected to one another, and are connected to one end of the resistor 23D.

One end of the resistor 24A is grounded. Further, the other end of the resistor 23A is connected to the other end of the resistor 24A and one end of the resistor 24B. The other end of the resistor 23B is connected to the other end of the resistor 24B and one end of the resistor 24C. The other end of the resistor 23C is connected to the other end of the resistor 24C and one end of the resistor 24D. The other end of the resistor 23D is connected to the other end of the resistor 24D, one end of the resistor 25, and the output terminal 7. The other end of the resistor 25 is grounded.

Note that, resistances of the resistors 23A through 23D and 25 are the same as each other, and the resistances of the resistors 24A through 24D are the same as each other. Moreover, each of the resistances of the resistors 23A through 23D and 25 is about twice as large as each of the resistances of the resistors 24A through 24D.

The 4-bit test signals, which are supplied through the respective signal lines Sig0T through Sig3T (see FIG. 1), are respectively supplied to the input terminals 5A through 5D of the DA conversion circuit 6 shown in FIG. 2. Then, the DA conversion circuit 6 generates an analog voltage having any one of 16 voltage levels (amplitudes) which are determined to fall within a range of 0V to a voltage supplied from the reference voltage source. The 16 voltage levels (amplitudes) correspond to respective 16 digital values “0000” through “1111” (i.e., sexadecimal in total) of the test signals. It is preferable that the 16 voltage levels (amplitudes) monotonously increase as the digital values increase. The DA conversion circuit 6 shown in FIG. 2 outputs the analog voltage thus generated, via the output terminal 7. Note in the DA conversion circuit 6 shown in FIG. 2 that an arbitrary voltage can be externally supplied, instead of the voltage supplied from the reference voltage source.

FIG. 3 is a view illustrating another example of a specific circuit configuration of the DA conversion circuit 6.

The DA conversion circuit 6 shown in FIG. 3 includes inverters 30A through 30D, p-transistors 31A through 31D, and resistors 32A through 32D.

The input terminal 5A is connected to an input terminal of the inverter 30A. An output terminal of the inverter 30A is connected to a gate terminal of the p-transistor 31A. A source terminal of the p-transistor 31A is connected to a reference voltage source (not illustrated). A drain terminal of the p-transistor 31A is connected to the output terminal 7 via the resistor 32A.

The input terminal 5B is connected to an input terminal of the inverter 30B. An output terminal of the inverter 30B is connected to a gate terminal of the p-transistor 31B. A source terminal of the p-transistor 31B is connected to a reference voltage source (not illustrated). A drain terminal of the p-transistor 31B is connected to the output terminal 7 via the resistor 32B.

The input terminal 5C is connected to an input terminal of the inverter 30C. An output terminal of the inverter 30C is connected to a gate terminal of the p-transistor 31C. A source terminal of the p-transistor 31C is connected to a reference voltage source (not illustrated). A drain terminal of the p-transistor 31C is connected to the output terminal 7 via the resistor 32C.

The input terminal 5D is connected to an input terminal of the inverter 30D. An output terminal of the inverter 30D is connected to a gate terminal of the p-transistor 31D. A source terminal of the p-transistor 31D is connected to a reference voltage source (not illustrated). A drain terminal of the p-transistor 31D is connected to the output terminal 7 via the resistor 32D.

In a case where the resistor 32D has a resistance of R, then the resistor 32C has a resistance of 2×R, the resistor 32B has a resistance of 4×R, and the resistor 32A has a resistance of 8×R.

The 4-bit test signals, which are supplied through the respective signal lines Sig0T through Sig3T (see FIG. 1), are respectively supplied to the input terminals 5A through 5D of the DA conversion circuit 6 shown in FIG. 3. Then, the DA conversion circuit 6 generates a current having any one of 16 current values (amplitudes) which are determined to fall within a range of 0A to a predetermined current. The 16 currents (amplitudes) correspond to respective 16 digital values “0000” through “1111” (i.e., sexadecimal in total) of the test signals. It is preferable that the 16 currents (amplitudes) monotonously increase as the digital values increase. The DA conversion circuit 6 shown in FIG. 3 outputs the current thus generated via the output terminal 7.

More specifically, according to the DA conversion circuit 6 shown in FIG. 3, a current Ia (note that, the current value Ia is 1/16 of a current I) flows through the resistor 32A, a current 2Ia flows through the resistor 32B, a current 4Ia flows through the resistor 32C, and a current 8Ia flows through the resistor 32D. Appropriate combinations of the currents Ia, 2Ia, 4Ia, and 8Ia made in accordance with the respective digital values allow an arbitrary generation of and outputting of a current having any one of the above 16 current levels. Note that the DA conversion circuit 6 shown in FIG. 2 is a known DA conversion circuit including a known DA conversion circuit having a R-2R ladder circuit. Further, the DA conversion circuit 6 shown in FIG. 3 is a known DA conversion circuit including a simple current adding circuit. Accordingly, detailed explanations as to operation principles of the DA conversion circuits are omitted.

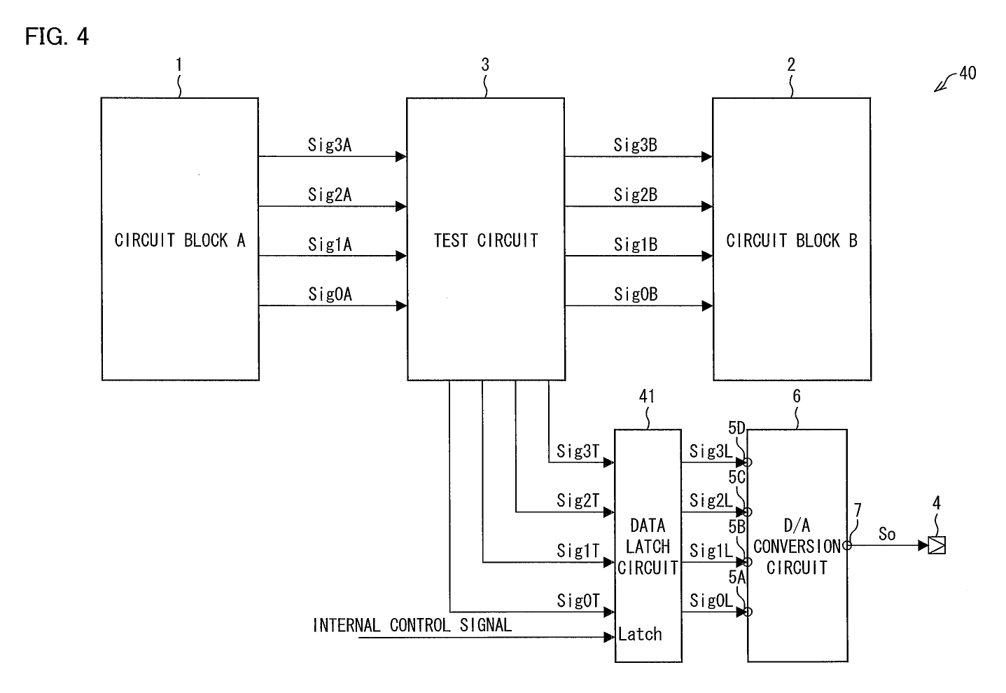

FIG. 4 is a block diagram illustrating a schematic structure of another semiconductor integrated circuit of the present invention.

A semiconductor integrated circuit 40 shown in FIG. 4 includes a data latch circuit (holding circuit) 41, in addition to the configuration of the semiconductor integrated circuit 10 shown in FIG. 1.

The data latch circuit 41 is provided between the test circuit 3 and the DA conversion circuit 6.

More specifically, the other end of the signal line Sig0T is connected to one end of a signal line Sig0L via the data latch circuit 41. The other end of the signal line Sig1T is connected to one end of a signal line Sig1L via the data latch circuit 41. The other end of the signal line Sig2T is connected to one end of a signal line Sig2L via the data latch circuit 41. The other end of the signal line Sig3T is connected to one end of a signal line Sig3L via the data latch circuit 41. Further, the DA conversion circuit 6 is connected to: other ends of the signal lines Sig0L, Sig1L, Sig2L, and Sig3L which are connected to the input terminals 5A, 5B, 5C, and 5D of the DA conversion circuit 6, respectively.

The data latch circuit 41 is a known latch circuit. In a case where the data latch circuit 41 receives the test signals supplied through the signal lines Sig0T through Sig3T, the data latch circuit 41 holds the test signals for a predetermined period of time.

Although not illustrated, the semiconductor integrated circuit 40 further includes an internal control device such as a CPU (Central Processing Unit) for carrying out overall control with respect to various operations of the circuit block 1 and/or the circuit block 2. It is possible to appropriately select (i) the period during which the data latch circuit 41 holds the test signals and (ii) the timing of sampling at the data latch circuit 41 in accordance with a function of a signal line for transmitting a specific internal control signal which is supplied from the internal control device. For example, the data latch circuit 41 holds the test signals when a signal (READ signal), which causes the internal control device to read out information from the semiconductor integrated circuit, becomes active.

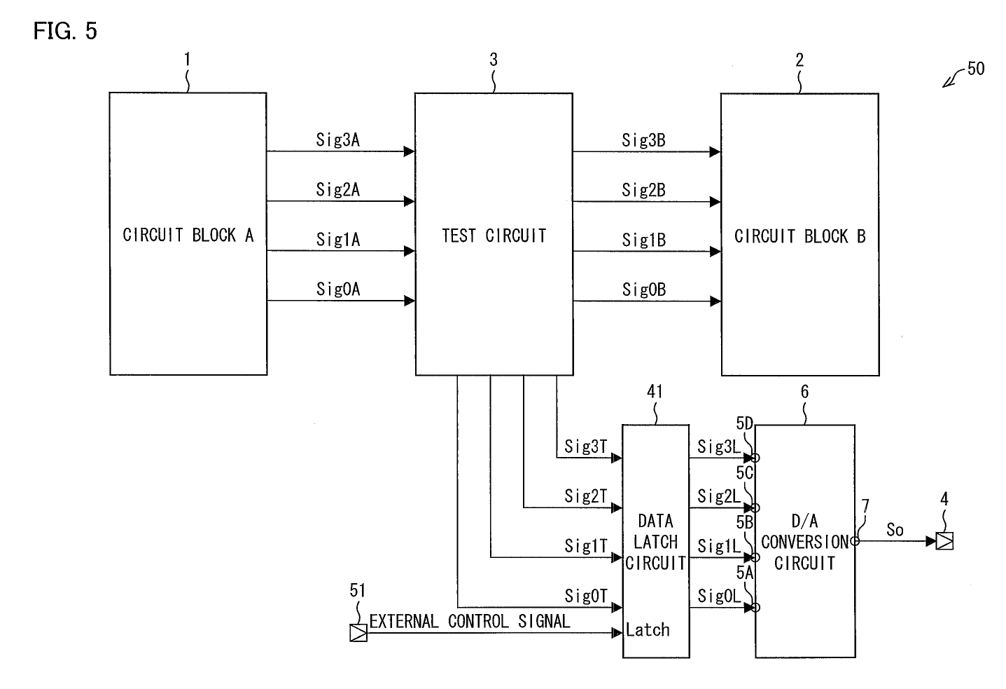

FIG. 5 is a block diagram illustrating a schematic configuration of a modified example of the semiconductor integrated circuit 40 shown in FIG. 4.

A semiconductor integrated circuit 50 shown in FIG. 5 has the same main configuration as the semiconductor integrated circuit 40 shown in FIG. 4.

Note that the semiconductor integrated circuit 50 shown in FIG. 5 does not need the internal control device but is configured so that an external control device (not illustrated) is externally connected to the semiconductor integrated circuit 50 via a terminal 51. Note that the external control device has a function of appropriately setting a period during which the data latch circuit 41 holds the test signals, by supplying an external control signal to the data latch circuit 41. The period during which the data latch circuit 41 holds the test signals is appropriately set in accordance with the external control signal supplied by the external control device. This makes it possible to appropriately set the period during which the data latch circuit 41 holds the test signals to an arbitrary period, independently of an operation status(es) of the circuit block 1 and/or the circuit block 2.

Each of the semiconductor integrated circuit 40 shown in FIG. 4 and the semiconductor integrated circuit 50 shown in FIG. 5 includes the data latch circuit 41, provided so as to be followed by the DA conversion circuit 6, in which the period during which the test signals are held is determined in accordance with the internal control signal or the external control signal, respectively. This causes the data latch circuit 41 to hold, for a target period of time, the test signals to be supplied to the DA conversion circuit 6, thereby to allow holding of an analog signal (analog value) which is to be outputted from the DA conversion circuit 6 via the signal line So

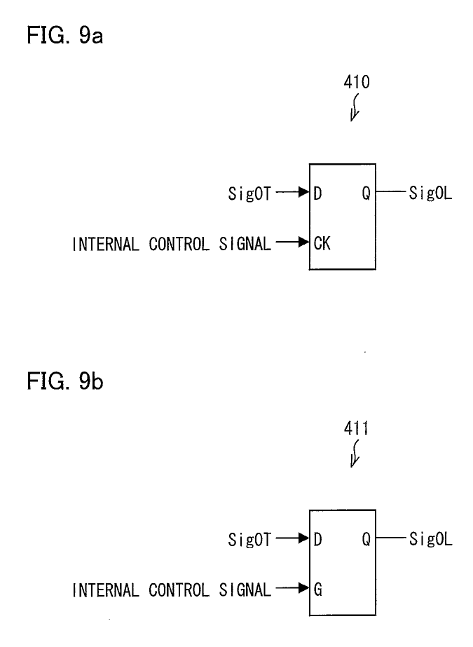

An example of a specific circuit configuration of the data latch circuit 41 includes a known DFF (Delay Flip-Flop) for a combination of (i) the respective signal lines Sig0T through Sig3T and (ii) the respective signal lines Sig0L through Sig3L. The signal lines Sig0L through Sig3L are connected to the signal lines Sig0T through Sig3T, respectively, via the data latch circuit 41. In each of the combinations, (i) the other end of a corresponding one of the signal lines Sig0T through Sig3T is connected to a data input terminal of a DFF, (ii) a clock input terminal of the DFF is connected to a signal line via which the data latch circuit 41 receives an internal control signal, and (iii) an output terminal of the DFF is connected to the one end of a corresponding one of the signal lines Sig0L through Sig3L which is to be connected to the corresponding one of the signal lines Sig0T through Sig3T via the data latch circuit 41. The following explains, as an example in detail, a combination of the signal line Sig0T and the signal line Sig0L, with reference to FIG. 9a. In a DFF 410 shown in FIG. 9a, a data input terminal D is connected to the other end of the signal line Sig0T. A clock input terminal CK is connected to a signal line via which the data latch circuit 41 receives an internal control signal. An output terminal Q is connected to the one end of the signal line Sig0L.

Moreover, in another example of a specific circuit configuration of the data latch circuit 41 includes a known D latch IC (Delay Latch Integrated Circuit) for a combination of (i) the respective signal lines Sig0T through Sig3T and (ii) the respective signal lines Sig0L through Sig3L. The signal lines Sig0L through Sig3L are connected to the signal lines Sig0T through Sig3T, respectively, via the data latch circuit 41. In each of the combinations, (i) the other end of a corresponding one of the signal lines Sig0T through Sig3T is connected to a data input terminal of a D latch IC, (ii) a gate terminal of the D latch IC is connected to a signal line via which the data latch circuit 41 receives an internal control signal, and (iii) an output terminal of the D latch IC is connected to the one end of a corresponding one of the signal lines Sig0L through Sig3L which is to be connected to the corresponding one of the signal lines Sig0T through Sig3T via the data latch circuit 41. The following explains, as an example in detail, a combination of the signal line Sig0T and the signal line Sig0L, with reference to FIG. 9b. In a D latch IC 411 shown in FIG. 9b, a data input terminal D is connected to the other end of the signal line Sig0T. A gate terminal G is connected to a signal line via which the data latch circuit 41 receives an internal control signal. An output terminal Q is connected to the one end of the signal line Sig0L.

Note that each of the internal control signals in FIG. 9a and FIG. 9b can be substituted with an external control signals (see FIG. 5). Moreover, known and conventional arts can deal with how the test signal is held in a case where a test signal is supplied to the DFF 410 or the D latch IC 411 which serves as the data latch circuit 41.

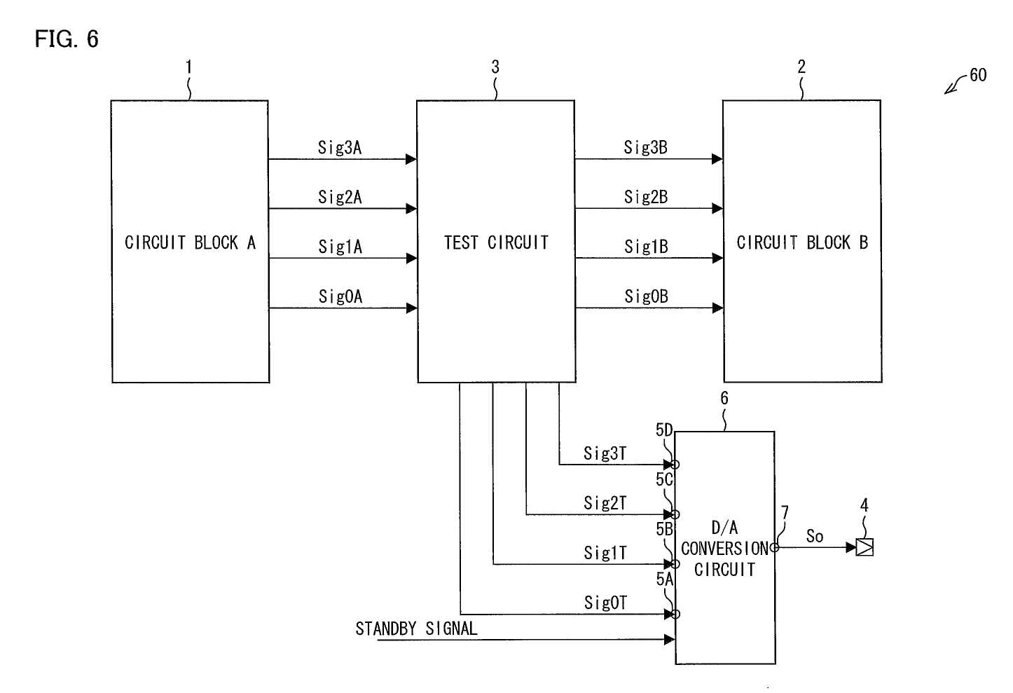

FIG. 6 is a block diagram illustrating a schematic structure of a further semiconductor integrated circuit of the present invention.

A semiconductor integrated circuit 60 shown in FIG. 6 has the same main configuration as the semiconductor integrated circuit 10 shown in FIG. 1.

However, it should be noted that the semiconductor integrated circuit 60 shown in FIG. 6 can suspend an operation of the DA conversion circuit 6 in response to a standby signal.

With the configuration, it is possible that the semiconductor integrated circuit has low power consumption, by suspending the operation of the DA conversion circuit 6 for a predetermined period of time in a case where no function of the DA conversion circuit 6 is needed. Note that the period during which the operation of the DA conversion circuit is suspended can be determined, in accordance with an operation status(es) of the circuit block 1 and/or the circuit block 2, by the foregoing internal control device, or can be determined arbitrarily independently of the operation status(es).

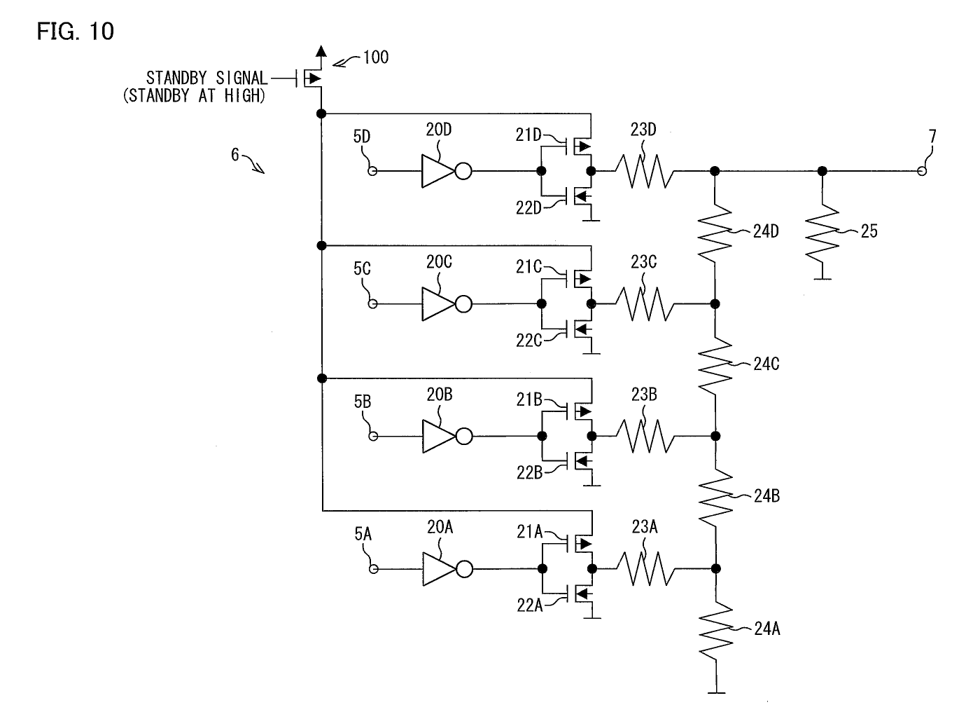

In order to suspend the operation of the DA conversion circuit 6 in response to a standby signal in a case where the DA conversion circuit 6 shown in FIG. 2 is employed, it is necessary to employ a circuit configuration, for example, in which the DA conversion circuit 6 further includes a p-transistor 100 as shown in FIG. 10. In the p-transistor 100, (i) a gate terminal is connected to a signal line (not illustrated) through which the standby signal is supplied, (ii) a source terminal is connected to the foregoing reference voltage source (not illustrated) for supplying a voltage VDD or determining a voltage of an analog signal to be outputted, and (iii) a drain terminal is connected to the source terminals of the respective p-transistors 21A through 21D. That is, the p-transistor 100 is provided so as to be located between the reference voltage source and a connecting point of the source terminals of the respective p-transistors 21A through 21D. The standby signal is supplied to the p-transistor 100 as a binary signal of a high level and a low level in general. In a case where the standby signal is the high level, the p-transistor 100 is turned off, so that no voltage (power source) is applied to the source terminals of the respective p-transistors 21A through 21D. This causes a suspension of the operation of the DA conversion circuit 6.

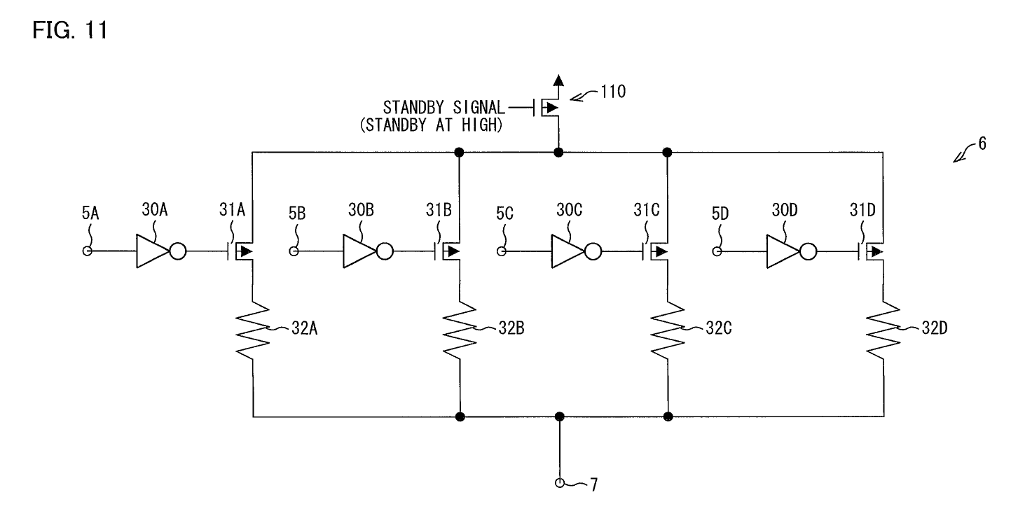

In order to suspend the operation of the DA conversion circuit 6 in response to the standby signal in a case where the DA conversion circuit 6 shown in FIG. 3 is employed, it is necessary to employ a circuit configuration, for example, in which the DA conversion circuit 6 further includes a p-transistor 110 as shown in FIG. 11. In the p-transistor 110, (i) a gate terminal is connected to a signal line (not illustrated) through which the standby signal is supplied, (ii) a source terminal is connected to the foregoing reference voltage source (not illustrated) for supplying a voltage VDD or determining a voltage of the analog signal to be outputted, and (iii) a drain terminal is connected to the source terminals of the respective p-transistors 31A through 31D. That is, the p-transistor 110 is provided so as to be located between the reference voltage source and a connecting point of the source terminals of the respective p-transistors 31A through 31D. The standby signal is supplied to the p-transistor 110 as a binary signal of a high level and a low level in general. In a case where the standby signal is the high level, the p-transistor 110 is turned off, so that no voltage (power source) is applied to the source terminals of the respective p-transistors 31A through 31D. This causes a suspension of the operation of the DA conversion circuit 6.

Note that, in the semiconductor integrated circuits of the present invention, it is possible to increase the number of bits of the test signals, by improving the precision of an external measuring device (not illustrated). This allows a further reduction in the number of the external output terminals. Here, each of the semiconductor integrated circuits is assumed to use the test circuit 3 for outputting, for example, 4-bit digital signals. However, in a case where a test circuit 3 for outputting 8-bit digital signals is used, the number of the output terminal can be also reduced to one.

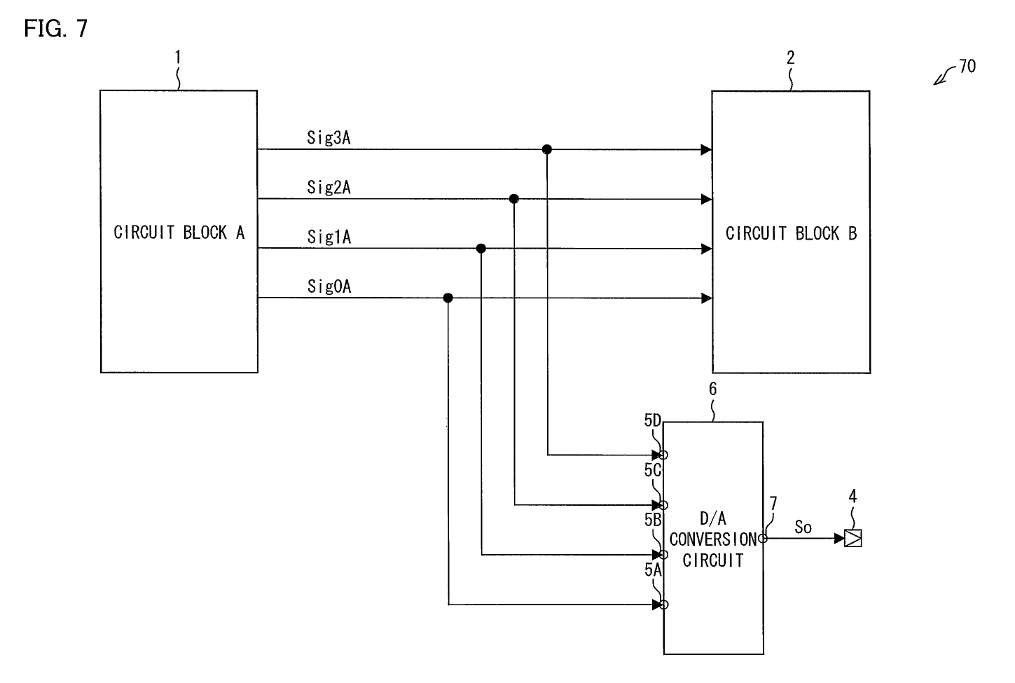

Moreover, the test circuit can be omitted from the semiconductor integrated circuit of the present embodiment (see a semiconductor integrated circuit 70 shown in FIG. 7). In this case, digital signals, which are supplied from the circuit block 1 through the respective signal lines Sig0A through Sig3A, are supplied to the respective input terminals 5A through 5D of the DA conversion circuit 6, which are respectively connected to the signal lines Sig0A through Sig3A. The DA conversion circuit 6 converts the digital signals thus received into an analog signal, and outputs the analog signal to the signal line So, via the output terminal 7. The analog signal, which is outputted via the signal line So, is externally outputted via the external output terminal 4.

Note that the present embodiment deals with the example in which a binary digital signal is used as the encoded signal. However, the encoded signal is not limited to the digital signal. That is, any encoded signal, such as notation system of base n (n is a natural number) (e.g., a binary signal), can be used as the encoded signal.

The present invention is not limited to the description of the embodiments above, but may be altered by a skilled person in the art within the scope of the claims. An embodiment made based on a proper combination of technical means disclosed in different embodiments is also encompassed in the technical scope of the present invention.

In order to attain the objects, the semiconductor integrated circuit of the present invention includes: a test circuit for (i) checking whether or not a circuit operates normally and (ii) outputting an encoded signal indicating a result thus checked; and an analog conversion circuit for (i) converting the encoded signal supplied from the test circuit into an analog signal and (ii) externally outputting the analog signal.

With the configuration, the test circuit supplies to the analog conversion circuit the encoded signal indicative of a checked result as to whether or not the circuit operates normally. The analog conversion circuit converts the encoded signal into an analog signal which can cause digital signals such as binary digital signals to be changed into a multiple-value. Then, the analog signal thus obtained is externally outputted. This makes it possible to convert a multiple-bit digital signal (various types of encoded signals) into a single analog signal, and then externally output such a single analog signal. As such, according to the semiconductor integrated circuit of the present invention, it is possible to reduce the number of output terminals via which the signal, indicating the result checked by the test circuit, is outputted.

Moreover, with the configuration, it is possible, without particularly thinking out the configuration of the test circuit itself, to reduce the number of output terminals via which the signal, indicating the result checked by the test circuit, is outputted. This allows a known test circuit to be used, thereby avoiding the complex configuration of the test circuit.

For the reasons described above, the semiconductor integrated circuit of the present invention is suitable for miniaturization.

Moreover, in the semiconductor integrated circuit of the present invention, the analog conversion circuit generates an analog voltage or a current whose amplitude varies according to a value of the encoded signal, and externally outputs the analog voltage or the current as the analog signal.

With the configuration, the analog voltage or the current, having an amplitude which changes according to a value of the encoded signal indicating the result checked by the test circuit, is generated. Then, the generated analog voltage or the generated current is externally outputted as an analog signal. For example, in a case where the encoded signals indicating the results checked by the test circuit are 4-bit digital signals, according to the digital signals, an analog voltage or a current, which is any one of 16 types of amplitudes corresponding to digital values of the digital signals, are generated, and is then externally outputted as an analog signal. This makes it possible to reduce the four signal lines, which are required before the conversion of the analog conversion circuit (i.e., when the encoded signal is transmitted), to a single line after the conversion of the analog conversion circuit (i.e., when the analog signal is delivered). Accordingly, it is sufficient to provide a single output terminal, not four, for outputting a signal indicating the result checked by the test circuit can be reduced from four to one.

Moreover, the semiconductor integrated circuit of the present invention further includes: a holding circuit for holding, for a predetermined period, the encoded signal to be supplied to the analog conversion circuit.

In the configuration, the encoded signal is held for a predetermined period at the holding circuit, and then the encoded signal is supplied to the analog conversion circuit. This makes it possible to supply the encoded signal to the analog conversion circuit at a desired timing. Note that the holding period during which the holding circuit holds the encoded signal may be determined in accordance with how the circuit operates, or may be determined independently of how the circuit operates.

Moreover, in the semiconductor integrated circuit of the present invention: the analog conversion circuit suspends its operation for a predetermined period in response to a signal indicative of suspension of operation.

In the configuration, in a case where a function of the analog conversion circuit is not needed, its operation is suspended for a predetermined period, whereby reducing power consumption. Note that, the period during which the analog conversion circuit suspends its operation may be determined in accordance with how the circuit operates, or may be determined independently of how the circuit operates.

Moreover, in the semiconductor integrated circuit of the present invention: the analog conversion circuit has a fewer output terminal for the analog signal than input terminals for the encoded signals.

In the configuration, the number of the output terminal via which the signal indicative of the result checked by the test circuit is reduced. This makes it possible to miniaturize the semiconductor integrated circuit.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### INDUSTRIAL APPLICABILITY

The present invention is suitable for miniaturization of a semiconductor integrated circuit including a test circuit for (i) checking whether or not a circuit operates normally and (ii) outputting a digital signal indicating a result thus checked. As such, the present invention is applicable to a semiconductor integrated circuit which externally outputs a signal, in a normal operation and in a test mode of general semiconductor integrated circuits.

### REFERENCE SIGNS LIST

1 and 2: Circuit Block (Circuit)
3: Test Circuit
4: External Output Terminal
5A-5D: Input Terminal (Input Terminal for an Encoded Signal)
6: Digital/Analog Conversion Circuit (Analog Conversion Circuit)
7: Output Terminal (Output Terminal for an Analog Signal)
10, 40, 50, and 60: Semiconductor Integrated Circuit
41: Data Latch Circuit (Holding Circuit)

1. A semiconductor integrated circuit comprising:
a test circuit for (i) checking whether or not a circuit operates normally and (ii) outputting an encoded signal indicating a result thus checked; and
an analog conversion circuit for (i) converting the encoded signal supplied from the test circuit into an analog signal and (ii) externally outputting the analog signal.

2. The semiconductor integrated circuit as set forth in claim 1, wherein:
the analog conversion circuit generates an analog voltage whose amplitude varies according to a value of the encoded signal, and externally outputs the analog voltage as the analog signal.

3. The semiconductor integrated circuit as set forth in claim 1, wherein:
the analog conversion circuit generates a current whose amplitude varies according to a value of the encoded signal, and externally outputs the current as the analog signal.

4. The semiconductor integrated circuit as set forth in claim 1, further comprising:
a holding circuit for holding, for a predetermined period, the encoded signal to be supplied to the analog conversion circuit.

5. The semiconductor integrated circuit as set forth in claim 4, wherein:
the period during which the holding circuit holds the encoded signal is determined in accordance with how the circuit operates.

6. The semiconductor integrated circuit as set forth in claim 4, wherein:
the period during which the holding circuit holds the encoded signal is arbitrarily determined independently of how the circuit operates.

7. The semiconductor integrated circuit as set forth in claim 1, wherein:
the analog conversion circuit suspends its operation for a predetermined period in response to a signal indicative of suspension of operation.

8. The semiconductor integrated circuit as set forth in claim 7, wherein:
the period during which the analog conversion circuit suspends its operation is determined in accordance with how the circuit operates.

9. The semiconductor integrated circuit as set forth in claim 7, wherein:
the period during which the analog conversion circuit suspends its operation is arbitrarily determined independently of how the circuit operates.

10. The semiconductor integrated circuit as set forth in claim 1, wherein:
the analog conversion circuit has a fewer output terminal for the analog signal than input terminals for the encoded signals.
